(19) United States
(12) Patent Application Publication
(10) Pub. No.: US 2025/0076929 A1
(43) Pub. Date: Mar. 6, 2025

(54) DISPLAY APPARATUS

(71) Applicant: Samsung Display Co., Ltd., Yongin-Si (KR)

(72) Inventors: Jaesoo Jang, Yongin-si (KR); Jonghyuck Kim, Yongin-si (KR); Juyeop Seong, Yongin-si (KR); Heekwon Lee, Yongin-si (KR); Jaewon Jeong, Yongin-si (KR)

(21) Appl. No.: 18/792,558

(22) Filed: Aug. 2, 2024

(30) Foreign Application Priority Data
Sep. 1, 2023 (KR) 10-2023-0116273

(51) Int. Cl. G06F 1/16; H10K 59/80; H10K 77/10; H10K 102/00

(52) U.S. Cl. CPC G06F 1/1652; H10K 59/8722; H10K 59/8793; H10K 77/111; H10K 2102/311

(57) ABSTRACT

A display apparatus including a first display area, a second display area, and a folding area between the first display area and the second display area is presented. The display apparatus further includes a display panel having a display surface, a support member disposed under the display panel and including a folding structure and an opening disposed on the folding structure, and a planarization film in the opening of the support member, wherein a thickness of the folding structure in a first direction is greater than a thickness of the opening in the first direction, the first direction being orthogonal to the display surface.

### CROSS-REFERENCE TO RELATED APPLICATION

This application is based on and claims priority, under 35 U.S.C. § 119, to Korean Patent Application No. 10-2023-0116273 filed on Sep. 1, 2023 in the Korean Intellectual Property Office, the disclosure of which is incorporated by reference herein in its entirety.

### BACKGROUND

### 1. Field

One or more embodiments relate to a display apparatus.

### 2. Description of the Related Art

Mobility-based electronic devices have been widely used. Recently, tablet personal computers (PCs) in addition to small electronic devices, such as mobile phones, have been widely used as mobile electronic devices.

In order to support various functions, these mobile electronic devices include a display apparatus to provide visual information such as an image or a video to a user. Recently, as the sizes of other components for driving a display apparatus have been decreased, an area of the display apparatus in an electronic device has gradually increased, and a structure that may be bent by a certain angle from a flat state has been developed.

### SUMMARY

One or more embodiments include a display apparatus.

Additional aspects will be set forth in part in the description which follows and, in part, will be apparent from the description, or may be learned by practice of the presented embodiments of the disclosure.

According to one or more embodiments, a display apparatus includes a first display area, a second display area, and a folding area between the first display area and the second display area, the display apparatus further including a display panel having a display surface, a support member disposed under the display panel and including a folding structure and an opening disposed on the folding structure, and a planarization film in the opening of the support member, wherein a thickness of the folding structure in a first direction is greater than a thickness of the opening in the first direction. The first direction is orthogonal to the display surface.

The support member may include a first support portion in the first display area and a second support portion in the second display area.

The folding structure may include a plurality of holes passing through the support member.

The folding structure may be between the first portion and the second portion. The opening may be above the folding structure.

A length of the opening in a second direction crossing the first direction may be greater than a length of the folding structure in the second direction.

A thickness of the opening in the first direction may be equal to a thickness of the planarization film in the first direction.

The display apparatus may further include a first adhesive layer arranged in the opening and disposed under the planarization film.

A thickness of the planarization film in the first direction may be greater than a thickness of the first adhesive layer in the first direction.

The thickness of the opening in the first direction may be greater than the thickness of the planarization film in the first direction.

The sum of thicknesses of the first adhesive layer and the planarization film in the first direction may be equal to the thickness of the opening in the first direction.

The planarization film may include thermoplastic polyurethane (TPU).

The planarization film may include polyethylene terephthalate (PET).

The support member may include at least one of stainless steel, carbon fiber reinforced plastic, and glass fiber reinforced plastic.

The support member may include at least one of an aluminum alloy, a titanium alloy, and a magnesium alloy.

The display apparatus may further include a second adhesive layer between the display panel and the support member.

The display apparatus may further include a polarization film disposed above the display panel.

The display apparatus may further include a window disposed above the polarization film.

The display apparatus may further include a third adhesive layer between the polarization film and the window.

The display apparatus may further include a window protection member disposed above the window.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2A is a cross-sectional view of the display apparatus of FIG. 1 taken along a line I-l′ of FIG. 1, according to an embodiment;

FIG. 2B is a cross-sectional view illustrating a cover window of the display apparatus, according to an embodiment, in more detail;

FIG. 3 is a cross-sectional view of the display apparatus of FIG. 1 taken along a line I-l′ of FIG. 1, according to an embodiment;

FIG. 4 is a plan view schematically illustrating a display panel of the display apparatus, according to an embodiment;

FIG. 5 is a cross-sectional view of the display apparatus of FIG. 4 taken along a line II-II′ of FIG. 4; and

FIG. 6 is a cross-sectional view schematically illustrating the display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since various modifications and various embodiments are possible, specific embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

Hereinafter, embodiments will be described in detail with reference to the accompanying drawings, and the same or corresponding components are denoted by the same reference numerals, and the same reference numerals are assigned and redundant explanations will be omitted.

In the following embodiments, ordinal terms such as “first” and “second,” etc. are used for the purpose of distinguishing one element from another element, without limiting the elements to a particular order or sequence.

In the following embodiments, the singular expression includes a plurality of expressions unless the context is clearly different.

In the following embodiments, terms such as “comprising” or “having” are meant to indicate the presence of elements and features described in the specification, without excluding the possibility of one or more other features also being present.

In the following embodiments, when a portion such as a layer, a region, an element or the like is “on” other portions, this is not only when the portion is directly on other elements, but also when other elements are interposed therebetween.

In the drawings, for convenience of explanation, the sizes of elements may be exaggerated or reduced. For example, since the size and thickness of each component shown in the drawings are arbitrarily indicated for convenience of explanation, the disclosure is not limited to the illustration.

In the present specification, in the case where some embodiments may be implemented in the present specification, a specific process order may be performed differently from the order described. For example, two processes described in succession may be substantially performed at the same time, or in an order that is reverse of the order that is described.

In the present specification, “A and/or B” is A, B, or A and B. In addition, in the present specification, “at least one of A and B” is A, B, or A and B.

In the following embodiments, when a layer, a region, a component, etc. are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc. are electrically connected to each other in the present specification, the layer, the region, the component, etc. are directly electrically connected to each other, and/or the layer, the region, the component, etc. are indirectly electrically connected to each other with other layers, other regions and other components interposed between the layer, the region, and the components.

The x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

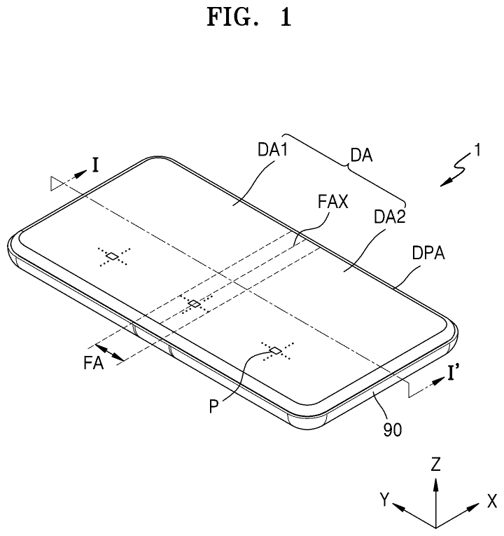

FIG. 1 is a perspective view schematically illustrating a display apparatus 1 according to an embodiment. The display apparatus 1 may have a rectangular shape. For example, the display apparatus 1 may have a rectangular planar shape having short sides in the first direction (e.g., x direction) and long sides in the second direction (e.g., y direction), as shown in FIG. 1. Edges in which the shorts sides in the first direction (e.g., x direction) and the long sides in the second direction (e.g., y direction) meet one another, may be rounded or formed at a right angle to have a certain curvature. The planar form of the display apparatus 1 is not limited to a rectangular shape but may be formed in other polygonal, oval, or unstructured shape.

In an embodiment, the display apparatus 1 may include a display area DA and a peripheral area DPA. The display area DA may be an area in which pixels are arranged and an image may be displayed, and the peripheral area DPA may be an area in which pixels are not arranged. The peripheral area DPA may surround at least part of the display area DA. The display area DA may include a first display area DA1, a second display area DA2, and a folding area FA. The first display area DA1 and the second display area DA2 may be at both sides of the folding area FA. The display apparatus 1 may be folded around the folding area FA.

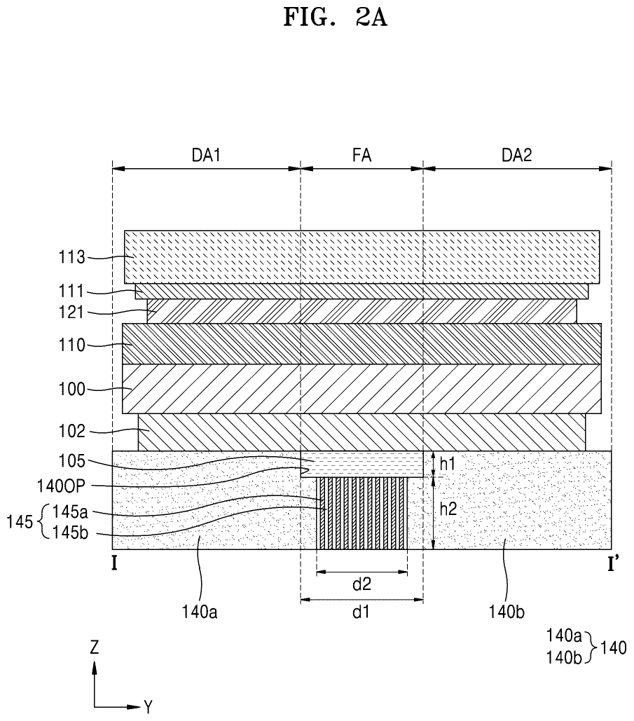

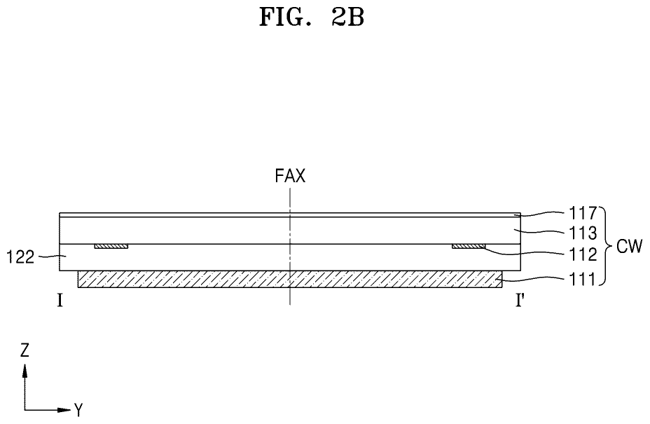

The display apparatus 1 described as above may have various shapes. In one embodiment, the display apparatus 1 may be provided as an unfoldable flat display. In another embodiment, at least part of the display apparatus 1 may be foldable. The display apparatus 1 may have an in-folding shape in which the display areas DA of the display panel (see 100 of FIG. 2A) face each other in the folded state, or an out-folding shape in which the display areas DA of the display panel 10 face outside in opposite directions in the folded state. In this disclosure, for convenience of explanation, the case where the display apparatus 1 is in-folded will be described in detail.

In an embodiment, the display apparatus 1 may include a display area DA and a peripheral area DPA. The display area DA may be an area where pixels are arranged and an image may be displayed. The surface of the display area DA where the image is presented is herein referred to as a “display surface.” The peripheral area DPA may be an area where pixels are not arranged. The peripheral area DPA may surround at least part of the display area DA. The display area DA may include a first display area DA1, a second display area DA2, and a folding area FA. The first display area DA1 and the second display area DA2 may be at both sides of the folding area FA.

In an embodiment, the display apparatus 1 may be folded around a folding axis FAX. An image may be displayed in the entire display area DA when the display area DA forms a flat surface so that a large screen may be implemented. In the folded state, the first display area DA1 and the second display area DA2 may be used as two screens, each displaying its own set of images instead of one continuous image that spans the entire display area DA.

The display panel (see 100 of FIG. 2A) may be a light-emitting display panel including a light-emitting element. For example, the display panel 100 may be an organic light-emitting display panel using an organic light-emitting diode including an organic light-emitting layer, an ultra-compact light-emitting diode display panel using a micro light-emitting diode (LED), a quantum dot light-emitting display panel using a quantum dot light-emitting diode including a quantum dot light-emitting layer, or an inorganic light-emitting display panel using an inorganic light-emitting device including an inorganic semiconductor.

The display panel 100 may be a rigid display panel that has rigidity and is not easily bent, or a flexible display panel that is easily bendable, foldable or rollable. For example, the display panel 100 may be a foldable display panel 100 that may be folded and unfolded repeatedly, a curved display panel 100 having a nonflat display surface, an angled display panel 100 having a bent area other than the display surface, a rollable display panel 100 that may be rolled and unrolled repeated, or a stretchable display panel 100.

The display panel 100 may be a transparent display panel 100 that allows objects or backgrounds disposed on a lower surface of the display panel 10 to be seen from the upper surface of the display panel 100. Alternatively, the display panel 100 may be a reflective display panel 100 that may reflect an object or background on the upper surface of the display panel 10.

A lower cover 90 may be disposed under the display panel 100. The lower cover 90 may constitute the exterior of a lower surface of the display apparatus 1. The lower cover 90 may include plastic, metal, or both plastic and metal.

FIG. 2A is a cross-sectional view of the display apparatus 1 taken along a line I-l′ of FIG. 1, according to an embodiment. FIG. 2B is a cross-sectional view illustrating a cover window CW of the display apparatus 1, according to an embodiment, in more detail.

Referring to FIG. 2A, the display apparatus 1 may include a window protection member 113, a window 111, a third adhesive layer 121, a polarization film 110, a display panel 100, a second adhesive layer 102, a planarization film 105, and a support member 140. FIG. 2A illustrates that the third adhesive layer 121 is between the polarization film 110 and the window 111, and embodiments are not limited thereto. Although not shown, layers may be coupled with an adhesive.

The polarization film 110 may be disposed on the display panel 100. The polarization film 110 may be attached to the display panel 100 to modify optical characteristics. The polarization film 110 may be attached to the display panel 100 so that external light reflection may be reduced, thereby enhancing the quality of the display apparatus 1.

The window 111 may be disposed above the polarization film 110. The window 111 may be adhered to an upper surface of the polarization film 110 through the third adhesive layer 121. In this case, the third adhesive layer 121 may be a pressure sensitive adhesive (PSA). However, this is not a limitation of the disclosure.

Although not shown, a protection member may be disposed on the display panel 100. For example, the protection member may be disposed between the display panel 100 and the polarization film 110. The protection member may be located on the display panel 100 to protect the display panel 100 from external shock.

In an embodiment, the window 111 and the window protection member 113 may be arranged above the display panel 100 and the polarization film 110. However, this is not a limitation of the disclosure. In another embodiment, a fourth adhesive layer (see 122 of FIG. 2B) and an opaque layer (see 112 of FIG. 2B) may be additionally arranged between the window 111 and the window protection member 113. FIG. 2B illustrates that the cover window CW including the window 111, the opaque layer 112, the window protection member 113 and a hard coating layer 117 is disposed above the display panel 100 and the polarization film 110, in more detail.

Referring to FIG. 2B, the cover window CW may include the window 111, the opaque layer 112, the window protection member 113, and the hard coating layer 117. The window 111 may be provided with ultra thin glass (UTGTM). However, one or more embodiments are not limited thereto. The window 111 may also be provided with a polymer resin.

The window protection member 113 may be disposed on the window 111. The window protection member 113 may be adhered to an upper surface of the window 111 through the fourth adhesive layer 122. The window protection member 113 may protect the window 111 from external shock and may prevent or minimize the occurrence of scratches on the upper surface of the window 111. The window protection member 113 may also be provided with a polymer resin. However, one or more embodiments are not limited thereto. The window protection member 113 may also be provided with an inorganic material.

The opaque layer 112 may be arranged between the window protection member 113 and the fourth adhesive layer 122. However, this is not a limitation of the disclosure. The opaque layer 112 may also be provided on part of the window protection member 113. The opaque layer 112 may be formed of an opaque material so that wirings or circuits of the display apparatus 1 may not be identified from the outside.

The hard coating layer 117 may be disposed on the window protection member 113. The hard coating layer 117 may be provided with an organic material such as a polymer resin or the like. However, one or more embodiments are not limited thereto. The hard coating layer 117 may also include an inorganic material.

The hard coating layer 117 may be the outermost layer of the cover window CW. In this case, the outermost layer of the cover window CW may refer to the outermost layer of the display apparatus 1. The outermost layer of the cover window CW may be a layer directly touched by a user, and when the outermost layer of the cover window CW is UTGTM or the window protection member 113, the touch may not feel pleasant to a user. The outermost layer of the cover window CW is provided as the hard coating layer 117 to provide a smooth and pleasant touch sensation to the user.

In an embodiment, a second adhesive layer 102 may be disposed under the display panel 100. The second adhesive layer 102 may be between the display panel 100 and a support member 140 disposed under the display panel 100, thereby attaching the display panel 100 to the support member 140. The second adhesive layer 102 may be a pressure sensitive adhesive (PSA). However, this is not a limitation of the disclosure.

The support member 140 may be disposed under the display panel 100. The support member 140 may include a first support portion 140a, a second support portion 140b, and a folding structure 145. The support member 140 may include the first support portion 140a that is at least partially in the first display area DA1, and the second support portion 140b that is at least partially in the second display area DA2. The first support portion 140a and the second support portion 140b may be spaced apart from each other in the y direction (“the second direction”). The folding structure 145 may be provided between the first support portion 140a and the second support portion 140b. The support member 140 may be disposed under the display panel 1400 to support the display panel 100.

In an embodiment, the support member 140 may include the folding structure 145. When the display apparatus 1 is folded, the shape or length of the folding structure 145 may vary. The folding structure 145 provided in the support member 140 may also be provided with the shape of unevenness, rotatably connected links, or the like. However, one or more embodiments are not limited thereto.

The folding structure 145 may include metal portions 145a in which a metal material is arranged, and holes 145b between the metal portions 145. In other words, the folding structure 145 may be provided with a plurality of holes 145b passing through the support member 140. As the folding structure 145 includes the metal portions 145a and the holes 145b between the metal portions 145, the support member 140 may be more easily folded.

When the display apparatus 1 is folded, the folding structure 145 may be folded at (or around) the folding axis FAX. The folding structure 145 may be provided so that the first support portion 140a and the second support portion 140b that are arranged at across the folding axis FAX from each other, for example symmetrically to each other. The support member 140 excluding the folding structure 145 may have a flat upper surface.

In an embodiment, the support member 140 may include at least one of glass, plastic, and metal. The support member 140 may include Stainless Steel (e.g., Steel Use Stainless, “SUS”), Carbon Fiber Reinforced Plastic, (CFRP) or Glass Fiber Reinforced Plastic (GFRP). In addition, the support member 140 may include aluminum (Al), titanium (Ti), magnesium (Mg) or a compound thereof. Alternatively, the support member 140 may include one among an Al alloy, a Ti alloy, and a Mg alloy. The folding structure 145 may include the same material as a material for the support member 140 or a different material from the material for the support member 140.

In an embodiment, the support member 140 may include an opening 140OP disposed on the folding structure 145. The opening 140OP of the support member 140 may overlap the folding structure 145. The planarization film 105 may be arranged in the opening 140OP of the support member 140. In other words, the planarization film 105 may be filled in the opening 140OP of the support member 140. The thickness of the opening 140OP of the support member 140 in a z direction (“the first direction”) and the thickness of the planarization film 105 in the z direction may be equal. The planarization film 105 may be arranged in the opening 140OP of the support member 140 so that the thickness of the foldable display apparatus 1 may be reduced and the folding structure 145 disposed under the planarization film 105 may not be recognized from the outside. Also, the planarization film 105 may be arranged only in the folding area FA, and the planarization film 105 may not be arranged in the first display area DA1 and the second display area DA2 so that impact in the first display area DA1 and the second display area DA2 may be enhanced.

The planarization film 105 is covers up the unevenness of the folding structure 145 disposed under the planarization film 105, and the planarization film 105 may be disposed above the folding structure 145 so that a surface (or an upper surface of the planarization film 105) on which the display panel 100 is to be disposed may be flat. When the planarization film 105 is arranged and the display apparatus 1 is seen from the above (e.g., z direction), the surface of the display apparatus 1 may be flat. The display panel 100 or the like may be stably disposed on the upper surface of the planarization film 105. However, this is not a limitation of the disclosure. In an embodiment, the planarization film 105 may be omitted.

The planarization film 105 may include at least one of plastic and metal. When the planarization film 105 includes plastic, the planarization film 105 may include thermoplastic polyurethane (TPU), polyimide (PI) or polyethylene terephthalate (PET). Also, when the planarization film 105 includes metal, the planarization film 105 may include SUS or a compound of Mg, Al, or Ti. However, these are not exhaustive lists of compositions for the planarization film 105.

A thickness h2 of the folding structure 145 in the z direction may be greater than a thickness h1 of the opening 140OP of the support member 140 in the z direction. In other words, the thickness h2 of the folding structure 145 in the z direction may be greater than the thickness of the planarization film 105 in the z direction. The thickness h2 of the folding structure 145 in the z direction may be greater than the thickness h1 of the opening 140OP of the support member 140 in the z direction so that, even when the support member 140 includes the opening 140OP in the folding area FA, the folding structure 145 may support upper structures, for example, the display panel 100, the planarization film 110, and the window 111.

A length d1 of the opening 140OP of the support member 140 in the y direction may be greater than a length d2 of the folding structure 145 in the y direction. In other words, the length d1 of the planarization film 105 arranged in the opening 140OP in the y direction may be greater than the length d2 of the folding structure 145 in the y direction. The planarization film 105 is provided with a larger length in the y direction than the folding structure 145 under the planarization film 105 so that the planarization film 105 may cover the unevenness of the folding structure 145.

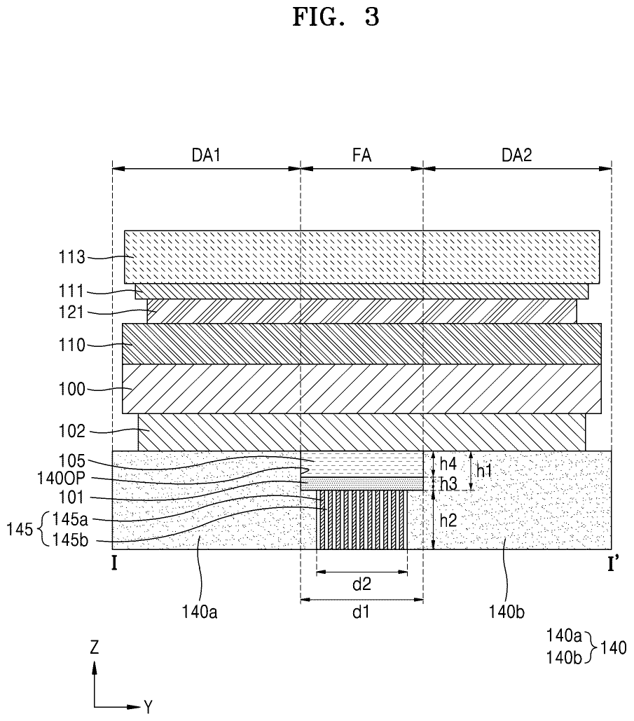

FIG. 3 is a cross-sectional view of the display apparatus 1 taken along a line I-l′ of FIG. 1, according to an embodiment.

Referring to FIG. 3, unlike in FIG. 2A, a planarization film and a first adhesive layer 101 may be arranged in an opening 140OP of a support member. The first adhesive layer 101 may be disposed under the planarization layer 105. The first adhesive layer 101 may be between the planarization layer and the folding structure to enhance an adhesive force between the planarization layer and the folding structure.

The firt adhesive layer may be disposed on the folding structure to prevent or minimize introduction of foreign substances into the folding structure of the support member. The first adhesive layer may include thermoplastic polyurethane (TPU). However, one or more embodiments are not limited thereto.

Since the planarization layer 105 and the first adhesive layer 101 are in the opening 140OP of the support member 140, the thickness h1 of the opening 140OP in the z direction may be equal to the sum of a thickness h3 of the first adhesive layer 101 in the z direction and a thickness h4 of the planarization layer 105 in the z direction. Also, since the planarization layer 105 and the first adhesive layer 101 are filled in the opening 140OP of the support member 140, the thickness h1 of the opening 140OP in the z direction may be greater than the thickness h4 of the planarization layer 105 in the z direction.

The thickness h4 of the planarization layer 105 in the z direction may be greater than the thickness h3 of the first adhesive layer 101 in the z direction disposed under the planarization layer 105. While the first adhesive layer 101 connects the planarization film 105 to the folding structure 145, the planarization layer 105 needs a certain thickness so as to complement for the uneven form of the folding structure 145 disposed under the planarization layer 105.

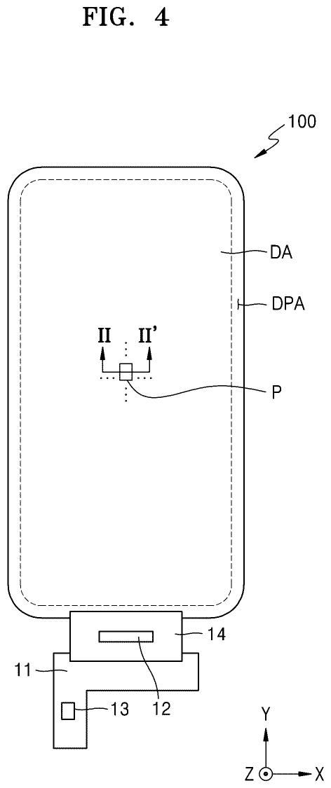

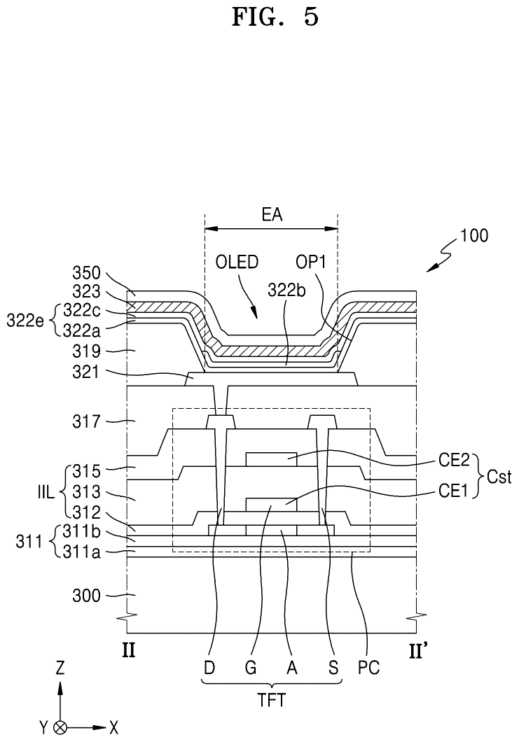

FIG. 4 is a plan view schematically illustrating a display panel of the display apparatus 1, according to an embodiment, and FIG. 5 is a cross-sectional view of the display apparatus 1 of FIG. 4 taken along a line II-II′ of FIG. 4.

Referring to FIGS. 4 and 5, the display panel 100 may include a display area DA and a peripheral area PA outside the display area DA. The display panel 100 may provide an image by using pixels P arranged in the display area DA.

The pixels P may be implemented as a display element such as an organic light-emitting diode OLED. Each pixel P may emit red, green, blue or white light, for example. The display area DA may be covered by the sealing member and protected from external air or moisture, etc.

A first soft film 14 may be attached to one side edge of the display panel 100. One side of the first soft film 14 may be attached to one side edge of the display panel 100 by using an anisotropic conductive film. The first soft film 14 may be a flexible film that is bendable.

A display driving portion 12 may be disposed above the first soft film 14. Control signals and power supply voltages may be applied to the display driving portion 12, and the display driving portion 12 may generate signals and voltages for driving the display panel 100 and output them. The display driving portion 12 may be formed of an integrated circuit (IC).

The display circuit board 11 may be attached to the other side of the first soft film 14. The other side of the first soft film 14 may be attached to an upper surface of the display circuit board 11 by using an anisotropic conductive film. The display circuit board 11 may be a flexible printed circuit board (FPCB) that may be bent, a rigid printed circuit board (PCB) that is hard and is not easily bent, or a composite PCB including both the rigid PCB and the FPCB.

A touch sensor driving portion 13 may be disposed above the display circuit board 11. The touch sensor driving portion 13 may be formed of an IC. The touch sensor driving portion 13 may be attached to the display circuit board 11. The touch sensor driving portion 13 may be electrically connected to touch electrodes of a touch screen layer (see 500 of FIG. 10) of the display panel 100 through the display circuit board 11.

The touch screen layer (see 500 of FIG. 10) of the display panel 100 may detect a user's touch input by using at least one of various touch methods such as a resistive type method, a capacitive type method, and the like. For example, when the touch screen layer (see 500 of FIG. 10) of the display panel 100 detects the user's touch input by using the capacitive type method, the touch sensor driving portion 13 may apply driving signals to driving electrodes among touch electrodes and may detect voltages charged in mutual capacitance between the driving electrodes and sensing electrodes (hereinafter, referred to as “mutual capacitance”) through the sensing electrodes among the touch electrodes, thereby determining whether or not the user has touched. The user's touch may include a contact touch and a proximity touch. A “contact touch” refers to an object such as the user's finger or a stylus being in direct contact with the cover window CW disposed on the touch screen layer. A “proximity touch” refers to an object such as the user's finger or a stylus being located close to the cover window CW, like hovering. The touch sensor driving portion 13 may transmit sensor data to the main processor according to detected voltages, and the main processor may analyze the sensor data so that touch coordinates in which touch input occurs, may be calculated.

Pixels of the display panel 100, a scan driving portion, and a power supply portion for supplying driving voltages for driving the display driving portion 12 may be additionally arranged above the display circuit board 11. Alternatively, the power supply portion may be integrated with the display driving portion 12, and in this case, the display driving portion 12 and the power supply portion may be formed of one IC.

The substrate 300 may include an insulating material such as glass, quartz, a polymer resin, or the like. In addition, the substrate 300 may include a polymer resin, such as polyethersulfone, polyacrylate, polyether imide, polyethylene naphthalate, polyethylene terephthalate, polyphenylene sulfide, polyarylate, polyimide, polycarbonate, or cellulose acetate propionate. The substrate 300 may have a multi-layered structure including a layer including the above-described polymer resin and an inorganic layer (not shown). For example, the substrate 300 may include two layers including the polymer resin described above and an inorganic barrier layer therebetween. The substrate 300 may be a rigid substrate or a flexible substrate that may be bent, folded or rolled.

The buffer layer 311 may be located on the substrate 300, may reduce or prevent penetration of foreign substances, moisture or external air from the lower portion of the substrate 300, and may provide a flat surface to the substrate 300. The buffer layer 311 may include an inorganic material such as oxide or nitride, an organic material, or an organic/inorganic composite material, and may have a single layer or multi-layered structure of the inorganic material and the organic material. A barrier layer (not shown) for preventing penetration of external air may be further arranged between the substrate 300 and the buffer layer 311. In an embodiment, the buffer layer 311 may include silicon oxide (SiO₂) or silicon nitride (SiNx). The buffer layer 311 may be provided in a structure in which a first buffer layer 311a and a second buffer layer 311b are stacked. In this case, the first buffer layer 311a may include silicon oxide (SiO₂), and the second buffer layer 311b may include silicon nitride (SiNx). Alternatively, the first buffer layer 311a may include silicon nitride (SiNx), and the second buffer layer 311b may include silicon oxide (SiO₂). Alternatively, the first buffer layer 311a and the second buffer layer 311b may include the same material.

A pixel circuit PC may be disposed above the buffer layer 311. The pixel circuit PC may include a thin-film transistor TFT and a storage capacitor Cst. The thin-film transistor TFT may be disposed above the buffer layer 311. The thin-film transistorTFT may include a semiconductor layer A, a gate electrode G, a source electrode S, and a drain electrode D. The thin-film transistor TFT may be connected to the organic light-emitting diode OLED to drive the organic light-emitting diode OLED.

The semiconductor layer A may be disposed on the buffer layer 311 and may include polysilicon. In an embodiment, the semiconductor layer A may include amorphous silicon. In an embodiment, the semiconductor layer A may include oxide of at least one material selected from the group consisting of indium (In), gallium (Ga), stanium (Sn), zirconium (Zr), vanadium (V), hafnium (Hf), cadmium (Cd), germanium (Ge), chromium (Cr), titanium (Ti), and zinc (Zn). The semiconductor layer A may include a channel region, and a source region and a drain region doped with impurities.

A first insulating layer 312 may be provided to cover the semiconductor layer A. The first insulating layer 312 may include an inorganic insulating material such as silicon oxide (SiOₓ), silicon nitride (SiNₓ), silicon oxynitride (SiO_{X}N_{Y}), aluminum oxide (Al₂O₃), titanium oxide (TiO₂), tantalum oxide (Ta₂O₅), hafnium oxide (HfO₂), or zinc oxide (ZnO₂). The first semiconductor layer 312 may have a single layer or multi-layered structure including the above-described inorganic insulating materials.

A gate electrode G may be disposed on the first insulating layer 312 to overlap the semiconductor layer A. The gate electrode G may have a single layer or multi-layered structure including molybdenum (Mo), Al, Cu, Ti, and the like. In an embodiment, the gate electrode G may have a single layer structure of Mo.

The second insulating layer 313 may be provided to cover the gate electrode G. The first insulating layer 313 may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The second semiconductor layer 313 may have a single layer or multi-layered structure including the above-described inorganic insulating materials.

An upper electrode CE2 of the storage capacitor Cst may be disposed above the second insulating layer 313. The upper electrode CE2 disposed on the second insulating layer 313 may overlap the gate electrode G disposed under the second insulating layer 313. The gate electrode G and the upper electrode CE that overlap each other with the second insulating layer 313 therebetween may constitute the storage capacitor Cst. In an embodiment, the gate electrode G may be a lower electrode CE1 of the storage capacitor Cst. In an embodiment, the lower electrode CE1 of the storage capacitor Cst may be provided as an additional independent component. In this case, the lower electrode CE1 and the gate electrode G may be spaced apart from each other by a certain distance.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu), and may have a single layer or multi-layered structure including the materials described above.

The third insulating layer 315 may be provided to cover the upper electrode CE2. The third insulating layer 315 may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The third insulating layer 315 may have a single layer or multi-layered structure including the above-described inorganic insulating materials.

A source electrode S and a drain electrode D may be disposed above the third insulating layer 315. The source electrode S and the drain electrode D may include a conductive material including Mo, Al, Cu, Ti, or the like, and may have a multi-layered or single layer structure including the materials described above. In an embodiment, the source electrode S and the drain electrode D may have a multi-layered structure of Ti/Al/Ti.

A planarization layer 317 may be disposed above the source electrode S and the drain electrode D. The planarization layer 317 may have a flat upper surface so that the pixel electrode 321 disposed on the planarization layer 317 may be formed flatly.

The planarization layer 317 may include an organic material, and may have a single layer or multilayered structure. The planarization layer 317 may include a general common use polymer such as Benzocyclobutene (BCB), polyimide, hexamethyldisiloxane (HMDSO), polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, or a vinyl alcohol-based polymer, or the like. The planarization layer 317 may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). When the planarization layer 317 is formed, chemical mechanical polishing may be performed on an upper surface of the planarization layer 317 so as to provide a flat upper surface after the planarization layer 317 is formed.

The planarization layer 317 may have a via hole extending through it. The pixel electrode 321 may contact with the source electrode S or the drain electrode D through the via hole in the planarization layer 317. The source S and the drain D extend through the insulating layers 312, 313, 315 to the semiconductor layer A of the thin-film transistor TFT.

FIG. 5 illustrates that one planarization layer 317 is provided. However, this is not a limitation of the disclosure and in another embodiment, two planarization layers 317 may be provided. Two planarization layers 317 may be advantageous in high integration.

A pixel electrode 321 may be disposed on the planarization layer 317. The pixel electrode 321 may include a transparent conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 321 may include a reflective layer including Ag, Mg, Al, Pt, Pd, Au, Ni, Nd, Ir, Cr, or a compound thereof. For example, the pixel electrode 321 may have a structure having layers formed of ITO, IZO, ZnO or In₂O₃ on/under the above-described reflective layer. In this case, the pixel electrode 321 may have a stack structure of ITO/Ag/ITO.

The pixel-defining layer 319 may be arranged on the planarization layer 317. The pixel-defining layer 319 may be disposed on the planarization layer 317 and may cover edges of the pixel electrode 321. A first opening OP1 for exposing at least part of the pixel electrode 321 may be defined in the pixel-defining layer 319. The size and shape of an emission area EA of the organic light-emitting diode OLED, i.e., the size of pixels P may be defined by the first opening OP1.

The pixel-defining layer 319 may be configured to increase a distance between edges of the pixel electrode 321 and the common electrode 323 on the pixel electrode 321 to prevent arc etc. from occurring in the edges of the pixel electrode 321. The pixel-defining layer 319 may be formed of an organic insulating material such as polyimide, polyamide, acryl resin, BCB, HMDSO, a phenol resin, or the like through a method such as spin coating.

Although not shown, a spacer for preventing imprint of masks may be further disposed above the pixel-defining layer 319. The spacer may be formed integrally with the pixel-defining layer 319. For example, the spacer and the pixel-defining layer 319 may be simultaneously formed in the same process by using a halftone mask process.

A light-emitting layer 322b may be arranged in the first opening OP1 defined in the pixel-defining layer 319 so as to correspond to the pixel electrode 321. The light-emitting layer 322b may include a polymer material or low molecular weight material, and may emit red, green, blue or white light.

An organic functional layer 322e may be disposed on and/under the light-emitting layer 322b. In an embodiment, the organic functional layer 322e may include a first functional layer 322a and/or a second functional layer 322c. In an embodiment, the first functional layer 322a or the second functional layer 322c may be omitted.

The first functional layer 322a may be disposed under the light-emitting layer 322b. The first functional layer 322a may have a single layer or multi-layered structure including an organic material. The first functional layer 322a may be a hole transport layer (HTL) having a single layer structure. Alternatively, the first functional layer 322a may include a hole injection layer (HIL) and a HTL. The first functional layer 322a may be integrally formed to correspond to a plurality of organic light-emitting diodes OLED included in the display area DA.

The second functional layer 322c may be disposed on the light-emitting layer 322b. The second functional layer 322c may have a single layer or multi-layered structure including an organic material. The second functional layer 322c may include an electron transport layer (ETL) and/or an electron injection layer (EIL). The second functional layer 322c may be integrally formed to correspond to the plurality of organic light-emitting diodes OLED included in the display area DA.

The opposite electrode 323 may be disposed on the second functional layer 322c. The opposite electrode 323 may include a conductive material having a low work function. For example, the opposite electrode 323 may include a (semi-) transparent layer including Ag, Mg, Al, Pt, Pd, Au, Ni, Nd, Ir, Cr, Li, Ca or an alloy thereof. Alternatively, the opposite electrode 323 may further include a layer such as ITO, IZO, ZnO or In₂O₃ on the (semi-) transparent layer including the above-described materials. The opposite electrode 323 may be integrally formed to correspond to a plurality of organic light-emitting diodes OLEDs included in the display area DA.

Layers from the pixel electrode 321 to the opposite electrode 323 may constitute an organic light-emitting diode OLED.

An upper layer 350 including an organic material may be disposed above the opposite electrode 323. The upper layer 350 may be a layer provided to protect the opposite electrode 323 and simultaneously to increase light extraction efficiency. The upper layer 350 may include an organic material having a higher refractive index than that of the opposite electrode 323. Alternatively, the upper layer 350 may be provided by stacking layers having different refractive indexes. For example, the upper layer 350 may be provided by stacking a high refractive index layer/a low refractive index layer/a high refractive index layer. In this case, the refractive index of the high refractive index layer may be equal to or greater than 1.7, and the refractive index of the low refractive index layer may be equal to or less than 1.3.

The upper layer 350 may further include lithium fluoride (LiF). Alternatively, the upper layer 350 may further include an inorganic insulating material such as silicon oxide (SiO₂) or silicon nitride (SiNₓ). The upper layer 350 may also be omitted if necessary. However, hereinafter, for convenience of explanation, the case where the upper layer 350 is disposed on the opposite electrode 323 will be described in detail.

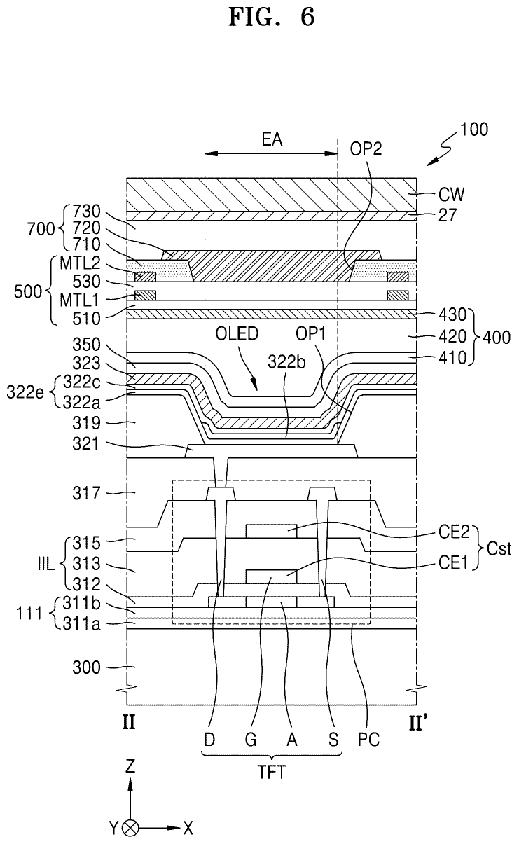

FIG. 6 is a cross-sectional view schematically illustrating the display apparatus 1 according to an embodiment. In FIG. 6, the same reference numerals as in FIG. 5 and thus, redundant descriptions are omitted.

Referring to FIG. 6, a thin-film encapsulation layer 400 may be disposed above the organic light-emitting diode OLED. The thin-film encapsulation layer 400 may include at least one inorganic encapsulation layer and at least one organic encapsulation layer. For example, the thin-film encapsulation layer 400 may include a first inorganic layer 410, an organic layer 420, and a second inorganic layer 430.

The first inorganic layer 410 and the second inorganic layer 430 may include one or more inorganic insulating materials. The inorganic insulating material may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂).

The organic layer 420 may include a polymer-based material. The polymer-based material may include an acryl-based resin, an epoxy-based resin, polyimide, polyethylene, or the like. For example, the organic membrane layer 420 may include an acrylic resin, such as polymethylmethacrylate, polyacrylic acid, and the like. The organic layer 320 may be formed by hardening monomer or by coating polymer.

A touch screen layer 500 may be disposed on the thin-film encapsulation layer 400. The touch screen layer 500 may include a first conductive layer MTL1 and a second conductive layer MTL2 including a sensing electrode and/or a trace line or the like. A first touch insulating layer 510 may be arranged between the thin-film encapsulation layer 400 and the first conductive layer MTL1, and a second touch insulating layer 530 may be arranged between the first conductive layer MTL1 and the second conductive layer MTL2.

The first conductive layer MTL1 and the second conductive layer MTL2 may include conductive materials. The conductive materials may include a conductive material including Mo, Al, Cu, Ti, or the like, and may have a multi-layered or single layer structure including the materials described above. In an embodiment, the first conductive layer MTL1 and the second conductive layer MTL2 may have a structure (Ti/Al/Ti) in which a Ti layer, an Al layer and a Ti layer are sequentially stacked.

The first touch insulating layer 510 and the second touch insulating layer 530 may include an inorganic insulating material and/or an organic insulating material. The inorganic insulating material may include an inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The organic insulating material may include an acryl-based organic material and an imide-based organic material.

A filter plate 700 as an optical functional layer may be disposed above the touch screen layer 500. The filter plate 700 may include a black matrix 710, a color filter 720, and an overcoat layer 730.

The black matrix 710 may be located in a non-emission area around the emission area EA and may surround the emission area EA. In an embodiment, the black matrix 710 may passivate a touch electrode of the touch screen layer 500. For example, as shown in FIG. 6, the second conductive layer MTL2 of the touch screen layer 500 may overlap the black matrix 710, and the second conductive layer MTL2 may be covered by the black matrix 710. The black matrix 710 may include an insulating material (e.g., an organic insulating material) including a black pigment or dye. The black matrix 710 may include a material that may be included in the pixel-defining layer 319.

The black matrix 710 may include a second opening OP2 to correspond to the emission area EA. The second opening OP2 defined in the black matrix 710 may be the same as or greater than the first opening OP1 defined in the pixel-defining layer 119.

The color filter 720 may be arranged in the emission area EA of the organic light-emitting diode OLED. The color filter 720 may have a red, green or blue pigment or dye according to the color of light emitted from the organic light-emitting diode OLED.

The overcoat layer 730 may be disposed to cover the black matrix 710 and the color filter 720, thereby planarizing upper surfaces thereof.

Although not shown, in an embodiment, an optical functional layer including a polarization plate (not the filter plate 700) may be disposed above the touch screen layer 500. In this case, the optical functional layer may include an anti-reflective layer. The anti-reflective layer may be configured to reduce reflectivity of light (external light) incident toward the display apparatus 1 from the outside.

In an embodiment, the anti-reflective layer may include a polarization film (see 110 of FIG. 2A). The polarization film (see 110 of FIG. 2A) may include a line polarization plate and a phase retarder film such as a quarter-wave (λ/4) plate. The phase retarder film may be disposed on the touch screen layer 500, and the line polarization plate may be disposed on the phase retarder film. In an embodiment, the anti-reflective layer may include a destructive interference structure. The destructive interference structure may include a first reflective layer and a second reflective layer that are arranged in different layers. First reflected light and second reflected light, which are reflected from the first reflective layer and the second reflective layer, respectively, may destructively interfere, thus reducing reflectivity of external light.

The cover window CW may be disposed above the filter plate 700. The cover window CW may be attached to the filter plate 700 through a sixth adhesive layer 27. In this case, the sixth adhesive layer 27 may be a pressure sensitive adhesive (PSA) or an optical clear adhesive (OCA).

Referring back to FIG. 2A and FIG. 3, in an embodiment, the planarization film 105 may be arranged in the opening 140OP of the support member 140 so that the planarization film 105 may be provided on an upper portion of the folding structure 145 of the folding area FA. With this configuration, the thickness of the foldable display apparatus may be reduced, the unevenness of the folding structure 145 may be covered up, and the folding structure 145 may not be recognized from the outside. The planarization film 105 may not be arranged in the first display area DA1 and the second display area DA2 so that impact of the display apparatus 1 in the first display area DA1 and the second display area DA2 may be enhanced.

According to one or more embodiments described above, a display apparatus having enhanced convenience, reliability and quality can be implemented. The scope of the disclosure is not limited by these effects.

It should be understood that embodiments described herein are to be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising a first display area, a second display area, and a folding area between the first display area and the second display area, the display apparatus further comprising:
a display panel having a display surface;
a support member disposed under the display panel and comprising a folding structure and an opening disposed on the folding structure; and
a planarization film in the opening of the support member,
wherein a thickness of the folding structure in a first direction is greater than a thickness of the opening in the first direction, the first direction being orthogonal to the display surface.

2. The display apparatus of claim 1, wherein the support member comprises a first support portion in the first display area and a second support portion in the second display area.

3. The display apparatus of claim 1, wherein the folding structure comprises a plurality of holes passing through the support member.

4. The display apparatus of claim 2, wherein the folding structure is between the first portion and the second portion.

5. The display apparatus of claim 1, wherein the opening is above the folding structure.

6. The display apparatus of claim 1, wherein a length of the opening in a second direction crossing the first direction is greater than a length of the folding structure in the second direction.

7. The display apparatus of claim 1, wherein a thickness of the opening in the first direction is equal to a thickness of the planarization film in the first direction.

8. The display apparatus of claim 1, further comprising a first adhesive layer arranged in the opening and disposed under the planarization film.

9. The display apparatus of claim 8, wherein a thickness of the planarization film in the first direction is greater than a thickness of the first adhesive layer in the first direction.

10. The display apparatus of claim 8, wherein a thickness of the opening in the first direction is greater than a thickness of the planarization film in the first direction.

11. The display apparatus of claim 8, wherein a sum of thicknesses of the first adhesive layer and the planarization film in the first direction is equal to a thickness of the opening in the first direction.

12. The display apparatus of claim 1, wherein the planarization film comprises thermoplastic polyurethane (TPU).

13. The display apparatus of claim 1, wherein the planarization film comprises polyethylene terephthalate (PET).

14. The display apparatus of claim 1, wherein the support member comprises at least one of stainless steel, carbon fiber reinforced plastic, and glass fiber reinforced plastic.

15. The display apparatus of claim 1, wherein the support member comprises at least one of an aluminum alloy, a titanium alloy, and a magnesium alloy.

16. The display apparatus of claim 1, further comprising a second adhesive layer between the display panel and the support member.

17. The display apparatus of claim 1, further comprising a polarization film disposed above the display panel.

18. The display apparatus of claim 17, further comprising a window disposed above the polarization film.

19. The display apparatus of claim 18, further comprising a third adhesive layer between the polarization film and the window.

20. The display apparatus of claim 18, further comprising a window protection member disposed above the window.
